(19) United States
(12) Patent Application Publication
(10) Pub. No.: US 2025/0089413 A1
(43) Pub. Date: Mar. 13, 2025

(54) DISPLAY APPARATUS

(71) Applicant: Samsung Display Co., Ltd., Yongin-Si (KR)

(72) Inventors: Hangjae Lee, Yongin-si (KR); Kiho Bang, Yongin-si (KR); Dongwon Kim, Yongin-si (KR); Minjung Na, Yongin-si (KR); Inhyuck Yeo, Yongin-si (KR); Wonsuk Choi, Yongin-si (KR)

(21) Appl. No.: 18/597,959

(22) Filed: Mar. 7, 2024

(30) Foreign Application Priority Data
Sep. 8, 2023 (KR) 10-2023-0119617

(51) Int. Cl. H01L 33/56; H01L 25/075; H01L 33/62

(52) U.S. Cl. CPC H10H 20/854; H01L 25/0753; H10H 20/857

(57) ABSTRACT

A display apparatus includes a display layer including a plurality of light-emitting diodes, a first insulating layer disposed on the display layer and including a first opening disposed in a gap between two light-emitting diodes adjacent to each other among the plurality of light-emitting diodes, and a second insulating layer disposed on the first insulating layer and including a second opening spaced apart from the first opening.

### CROSS-REFERENCE TO RELATED APPLICATION

This application is based on and claims priority under 35 U.S.C. § 119 to Korean Patent Application No. 10-2023-0119617, filed on Sep. 8, 2023, in the Korean Intellectual Property Office, the disclosure of which is incorporated by reference herein in its entirety.

### BACKGROUND

### 1. FIELD

One or more embodiments relate to a display apparatus, and more particularly, to a display apparatus including a light-emitting diode.

### 2. DESCRIPTION OF THE RELATED ART

A display apparatus may be an electronic apparatus, such as a mobile phone or a tablet personal computer (PC), or may be a portion of an electronic apparatus. A display apparatus may provide visual information, such as images or videos, to a user. Recent display apparatuses may include a structure with curved sides or corners and may display images even on the curved sides or corners. Display apparatuses may also include a display panel and a cover window disposed on the display panel to protect the display panel.

### SUMMARY

To implement a display apparatus with a curved structure, a display panel and a cover window may be bonded to each other and bent. At this time, cracks may occur in a specific layer of the display panel due to strong stress and high strain.

One or more embodiments include a display apparatus having a structure capable of relieving stress without reducing a thickness of a specific layer on which stress is concentrated. However, this is only an example and the scope of the disclosure is not limited thereby.

Additional aspects will be set forth in part in the description which follows and, in part, will be apparent from the description, or may be learned by practice of the presented embodiments of the disclosure.

According to one or more embodiments, a display apparatus includes a display layer including a plurality of light-emitting diodes, a first insulating layer disposed on the display layer and including a first opening disposed in a gap between two light-emitting diodes adjacent to each other among the plurality of light-emitting diodes, and a second insulating layer disposed on the first insulating layer and including a second opening spaced apart from the first opening.

In an embodiment, a portion of the second insulating layer may at least partially fill the first opening of the first insulating layer.

In an embodiment, the second opening may be disposed above one of the two light-emitting diodes adjacent to each other.

In an embodiment, in a plan view, the first opening may have a shape surrounding the second opening.

In an embodiment, the display apparatus may further include a touch electrode disposed on the second insulating layer and including a conductive line passing between the two light-emitting diodes adjacent to each other in a plan view, wherein the conductive line may be disposed above the first opening.

In an embodiment, the display apparatus may further include an encapsulation layer between the display layer and the first insulating layer, wherein the encapsulation layer may include a first inorganic encapsulation layer, an organic encapsulation layer disposed on the first inorganic encapsulation layer, and a second inorganic encapsulation layer disposed on the organic encapsulation layer and including a third opening disposed below the first opening.

In an embodiment, a depth of the first opening may be equal to a thickness of the first insulating layer, and a depth of the third opening may be less than or equal to a thickness of the second inorganic encapsulation layer.

In an embodiment, the display apparatus may further include an organic layer between the first insulating layer and the second insulating layer.

In an embodiment, the organic layer may include an opening disposed below the second opening.

In an embodiment, the second insulating layer may include a plurality of second openings, and one of the plurality of light-emitting diodes may overlap two or more of the plurality of second openings.

In an embodiment, the display apparatus may further include a display area in which the plurality of light-emitting diodes are arranged and a peripheral area arranged outside the display area, wherein the first opening and the second opening may be arranged in the display area.

According to one or more embodiments, a display apparatus includes a display layer including a plurality of light-emitting diodes, an encapsulation layer disposed on the display layer, and a touch layer disposed on the encapsulation layer. The touch layer includes a touch electrode, and a first insulating layer and a second insulating layer between the touch electrode and the encapsulation layer. The first insulating layer includes a first opening, the second insulating layer includes a second opening, and a center of the first opening and a center of the second opening are spaced apart from each other.

In an embodiment, a portion of the second insulating layer may at least partially fill the first opening.

In an embodiment, the second opening may be disposed above one of the plurality of light-emitting diodes.

In an embodiment, the touch electrode may include a conductive line and an opening defined by the conductive line. The conductive line of the touch electrode may be disposed above the first opening of the first insulating layer, and the opening of the touch electrode may be disposed above the second opening of the second insulating layer.

In an embodiment, the touch layer may further include a third insulating layer disposed on the second insulating layer, and the third insulating layer may be in direct contact with the first insulating layer at the second opening.

In an embodiment, the encapsulation layer may include a first inorganic encapsulation layer, an organic encapsulation layer on the first inorganic encapsulation layer, and a second inorganic encapsulation layer on the organic encapsulation layer. The second inorganic encapsulation layer may include a third opening disposed below the first opening of the first insulating layer.

In an embodiment, the first opening may pass through the first insulating layer, and the third opening may be located over at least a portion of the second inorganic encapsulation layer in a depth direction.

In an embodiment, the display apparatus may further include an organic layer between the first insulating layer and the second insulating layer.

In an embodiment, the display apparatus may further include a display area in which the plurality of light-emitting diodes are arranged and a peripheral area surrounding the display area, wherein the first opening and the second opening may be arranged in the display area.

### BRIEF DESCRIPTION OF THE DRAWINGS

The above and other aspects, features, and advantages of certain embodiments of the disclosure will be more apparent from the following description taken in conjunction with the accompanying drawings.

FIG. 1 is a perspective view schematically illustrating a display apparatus according to an embodiment.

FIG. 2 is an exploded perspective view schematically illustrating a display panel and a cover window of a display apparatus, according to an embodiment.

FIG. 3 is a perspective view schematically illustrating a display panel of a display apparatus, according to an embodiment.

FIG. 4 is a cross-sectional view of the display apparatus of FIG. 1 taken along line IV-IV′ of FIG. 1.

FIG. 5 is a cross-sectional view illustrating a portion of a display panel according to an embodiment.

FIG. 6 is an enlarged plan view illustrating a portion of a display panel according to an embodiment.

FIG. 7 is an enlarged cross-sectional view illustrating a portion of a display panel according to an embodiment.

FIGS. 8A, 8B, 8C and 8D are cross-sectional views schematically illustrating a process of manufacturing a display panel, according to an embodiment.

FIG. 9 is an enlarged cross-sectional view illustrating a portion of a display panel according to an embodiment.

FIGS. 10A, 10B, and 10C are cross-sectional views schematically illustrating a process of manufacturing a display panel, according to an embodiment.

FIG. 11 is an enlarged cross-sectional view illustrating a portion of a display panel according to an embodiment.

FIG. 12 is an enlarged cross-sectional view illustrating a portion of a display panel according to an embodiment.

FIG. 13 is an enlarged plan view illustrating a portion of a display panel according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in detail in the written description. Effects and features of the disclosure, and methods of achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings. When describing embodiments with reference to the accompanying drawings, the same or corresponding elements are denoted by the same reference numerals, and redundant descriptions thereof will be omitted.

It will be understood that, when an element such as a layer, film, region, or plate is referred to as being “on” another element, the element may be “directly on” the other element, and intervening elements may be present therebetween. Also, sizes of elements in the drawings may be exaggerated or reduced for convenience of explanation. For example, because sizes and thicknesses of elements in the drawings are arbitrarily illustrated for convenience of explanation, the disclosure is not limited thereto.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

It will be understood that although the terms “first,” “second,” etc. may be used herein to describe various elements, these elements should not be limited by these terms. These terms are only used to distinguish one element from another.

The singular forms as used herein are intended to include the plural forms as well unless the context clearly indicates otherwise.

It will be further understood that the terms “include” and/or “comprise” used herein specify the presence of stated features or elements, but do not preclude the presence or addition of one or more other features or elements.

In this specification, the expression “A and/or B” indicates only A, only B, or both A and B. In this specification, the expression “at least one of A and B” indicates only A, only B, or both A and B.

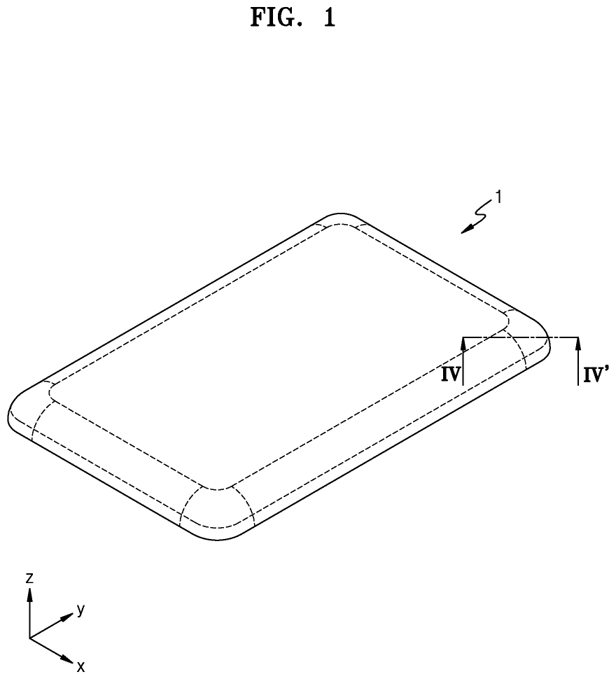

FIG. 1 is a perspective view schematically illustrating a display apparatus 1 according to an embodiment.

Referring to FIG. 1, the display apparatus 1 according to an embodiment is configured to display a moving image or a still image. The display apparatus 1 may be a portable electronic apparatus, such as a mobile phone, a smartphone, a tablet personal computer (PC), a mobile communication terminal, an electronic organizer, an e-book, a portable multimedia player (PMP), a navigation system, and an ultra mobile PC (UMPC). In addition, the display apparatus 1 may be an electronic apparatus, such as a television, a laptop, a monitor, a billboard, and an Internet of thing (IoT) device. In an embodiment, the display apparatus 1 may be a wearable device, such as a smart watch, a watch phone, a glass-type display, or a head mounted display (HMD).

In an embodiment, the display apparatus 1 may have a rectangular shape in a plan view. In an embodiment, the display apparatus 1 may have one of various shapes, such as a polygonal shape (e.g., a triangular shape, a rectangular shape, etc.), a circular shape, and an elliptical shape. In an embodiment, when the display apparatus 1 has a polygonal shape in a plan view, the polygon may have round corners. For convenience of explanation, a case where the display apparatus 1 has a rectangular shape with round corners in a plan view is mainly described.

The display apparatus 1 may have a short side in a first direction (e.g., an ±x direction) and a long side in a second direction (e.g., a ±y direction). In an embodiment, in the display apparatus 1, the length of the side in the first direction (e.g., the ±x direction) may be equal to the length of the side in the second direction (e.g., the ±y direction). In an embodiment, the display apparatus 1 may have a long side in the first direction (e.g., the ±x direction) and a short side in the second direction (e.g., the ±y direction). Each corner where the short side in the first direction (e.g., the ±x direction) meets the long side in the second direction (e.g., the ±y direction) may be round to have a certain curvature.

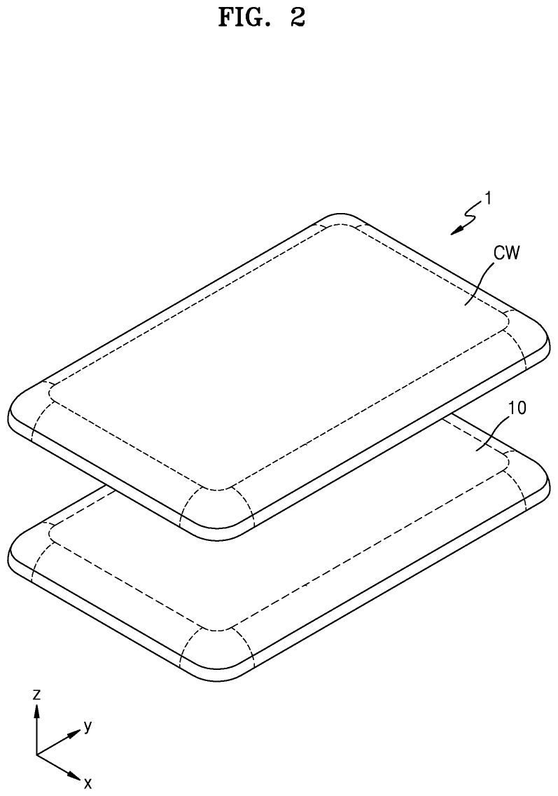

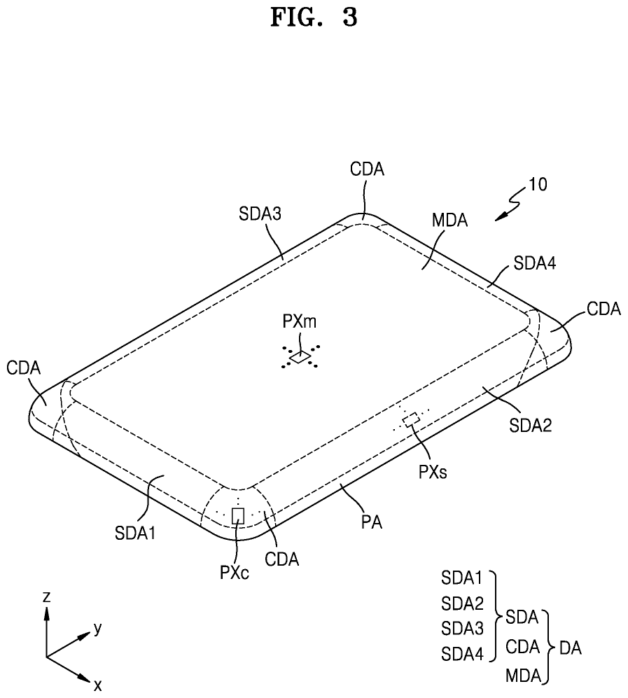

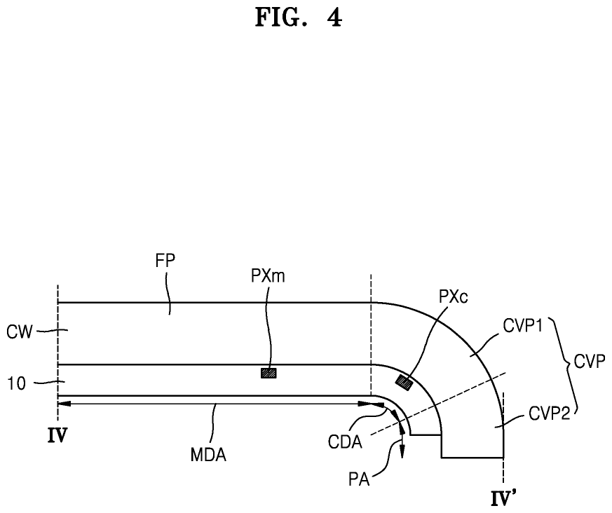

FIG. 2 is an exploded perspective view schematically illustrating a display panel 10 and a cover window CW of the display apparatus 1, according to an embodiment. FIG. 3 is a perspective view schematically illustrating the display panel 10 of the display apparatus 1, according to embodiment. FIG. 4 is a cross-sectional view of the display apparatus 1 of FIG. 1 taken along line IV-IV′ of FIG. 1.

Referring to FIGS. 2 to 4, the display apparatus 1 may include the display panel 10 and the cover window CW disposed on the display panel 10.

The display panel 10 may include a main display area MDA, a side display area SDA, and a corner display area CDA as a display area DA. The display panel 10 may include a peripheral area PA surrounding the display area DA.

The main display area MDA is an area arranged in the central portion of the display panel 10 and may be flat without being bent. The main display area MDA may occupy the largest proportion of the display area DA of the display panel 10, and thus may provide most of an image. The main display area MDA may include a short side in the ±x direction and a long side in the ±y direction, and each corner where the short side meets the long side may have a round rectangular shape.

At least a portion of the side display area SDA may be bent to include a curved surface, and may extend outward from each side of the main display area MDA. The side display area SDA may include a first side display area SDA1, a second side display area SDA2, a third side display area SDA3, and a fourth side display area SDA4. In some embodiments, at least one of the first side display area SDA1, the second side display area SDA2, the third side display area SDA3, or the fourth side display area SDA4 may be omitted.

The first side display area SDA1 may be an area that extends from a first side of the main display area MDA and is bent with a certain curvature. The first side display area SDA1 may extend from the lower side (or the −y direction side) of the main display area MDA. The first side display area SDA1 may be an area disposed on the lower surface of the display panel 10.

The second side display area SDA2 may be an area that extends from a second side of the main display area MDA and is bent with a certain curvature. The second side display area SDA2 may extend from the right side (or the +x direction side) of the main display area MDA. The second side display area SDA2 may be an area disposed on the right surface of the display panel 10.

The third side display area SDA3 may be an area that extends from a third side of the main display area MDA and is bent with a certain curvature. The third side display area SDA3 may extend from the left side (or the −x direction side) of the main display area MDA. The third side display area SDA3 may be an area disposed on the left surface of the display panel 10.

The fourth side display area SDA4 may be an area that extends from a fourth side of the main display area MDA and is bent with a certain curvature. The fourth side display area SDA4 may extend from the upper side (or the +y direction side) of the main display area MDA. The fourth side display area SDA4 may be an area disposed on the upper surface of the display panel 10.

The first to fourth side display areas SDA1, SDA2, SDA3, and SDA4 may each include a curved surface that is bent with a constant curvature. For example, the first side display area SDA1 and the fourth side display area SDA4 may each have a curved surface that is bent with respect to a bending axis extending in the ±x direction. The second side display area SDA2 and the third side display area SDA3 may each have a curved surface that is bent with respect to a bending axis extending in the ±y direction. The curvatures of the first to fourth side display areas SDA1, SDA2, SDA3, and SDA4 may be equal to or different from each other.

The corner display area CDA may be an area that extends from the corner of the main display area MDA and is bent with a certain curvature. The corner display area CDA may be between the first to fourth side display areas SDA1 to SDA4. For example, the corner display area CDA may be between the first side display area SDA1 and the second side display area SDA2, between the first side display area SDA1 and the third side display area SDA3, between the second side display area SDA2 and the fourth side display area SDA4, and between the third side display area SDA3 and the fourth side display area SDA4.

Because the corner display area CDA is between the adjacent side display areas SDA having curved surfaces that are bent in different directions, the corner display area CDA may include a curved surface in which curved surfaces bent in various directions are continuously connected to each other. In addition, when the curvatures of the adjacent side display areas SDA are different from each other, the curvature of the corner display area CDA may gradually change along the edge of the display apparatus 1. For example, when the curvature of the first side display area SDA1 is different from the curvature of the second side display area SDA2, the corner display area CDA between the first side display area SDA1 and the second side display area SDA2 may have a curvature that gradually changes depending on a position.

The display panel 10 may provide images by using main pixels PXm arranged in the main display area MDA, side pixels PXs arranged in the side display area SDA, and corner pixels PXc arranged in the corner display area CDA. Pixels, such as the main pixels PXm, the side pixels PXs, and the corner pixels PXc, may be implemented as display elements. The pixels may each include a red sub-pixel, a green sub-pixel, and a blue sub-pixel. In an embodiment, the pixels may each include a red sub-pixel, a green sub-pixel, a blue sub-pixel, and a white sub-pixel.

Individual images may be respectively provided to the main display area MDA, the side display area SDA, and the corner display area CDA, or a portion of an image may be provided thereto. Because the display panel 10 provides images to the side display area SDA and the corner display area CDA as well as the main display area MDA, the proportion of the display area DA in the display apparatus 1 may increase. That is, in the display apparatus 1 having the same size, the area of the peripheral area PA may be reduced and the area of the display area DA may be increased.

The peripheral area PA may be disposed to completely or partially surround the periphery of the side display area SDA and the corner display area CDA. The peripheral area PA is an area where an image is not displayed, and various wirings and driving circuits may be arranged in the peripheral area PA. A shield such as a light blocking member may be provided in the peripheral area PA so that members arranged in the peripheral area PA are not visually recognized.

Referring to FIG. 4, the cover window CW may be disposed on the front surface of the display panel 10. The “front surface” of the display panel 10 may be defined as a surface facing a direction in which the display panel 10 provides an image. For example, the front surface in the main display area MDA may be a surface facing the +z direction, which is a direction in which an image is provided.

The cover window CW may cover and protect the display panel 10. The cover window CW may have high transmittance in order to transmit light emitted from the display panel 10, and may have a small thickness in order to minimize the weight of the display apparatus 1. In addition, the cover window CW may have strong strength and hardness in order to protect the display panel 10 from external impact.

The cover window CW may include a transparent material. The cover window CW may include, for example, glass or plastic. When the cover window CW includes plastic, the cover window CW may be flexible. The cover window 20 may include, for example, Ultra-Thin Glass (UTG®), the strength of which is strengthened by chemical strengthening or thermal strengthening. In an embodiment, the cover window CW may include UTG® and colorless polyimide (CPI). In an embodiment, the cover window CW may have a structure in which a flexible polymer layer is disposed on one surface of a glass substrate, or may include only a polymer layer.

The cover window CW may include a flat portion FP corresponding to the main display area MDA of the display panel 10, and a curved portion CVP corresponding to the side display area SDA and the corner display area CDA.

The flat portion FP of the cover window CW may be provided as a flat surface and may overlap the main display area MDA of the display panel 10. The curved portion CVP of the cover window CW may be provided as a curved surface. In this case, the curved portion CVP may have a constant curvature or a varying curvature. The curved portion CVP may include a first curved portion CVP1 and a second curved portion CVP2. The first curved portion CVP1 may be disposed to overlap the side display area SDA and the corner display area CDA of the display panel 10. The second curved portion CVP2 may be disposed to overlap the peripheral area PA of the display panel 10. The first curved portion CVP1 may be between the flat portion FP and the second curved portion CVP2.

A light blocking member (not shown) may be disposed on a portion of the second curved portion CVP2 of the cover window CW and may overlap the peripheral area PA of the display panel 10. The light blocking member may include a light blocking material. The light blocking material, may include, for example, a resin including carbon black, carbon nanotubes, and black dye. The light blocking member may cover the elements of the display panel 10 arranged in the peripheral area PA from being visible.

The display panel 10 may be disposed below the cover window CW. The cover window CW and the display panel 10 may be connected to each other by an adhesive member (not shown). The adhesive member may be an optically clear adhesive film (OCA) or an optically clear resin (OCR). In some embodiments, a lower protective film (not shown) may be further disposed below the display panel 10 so as to protect the display panel 10.

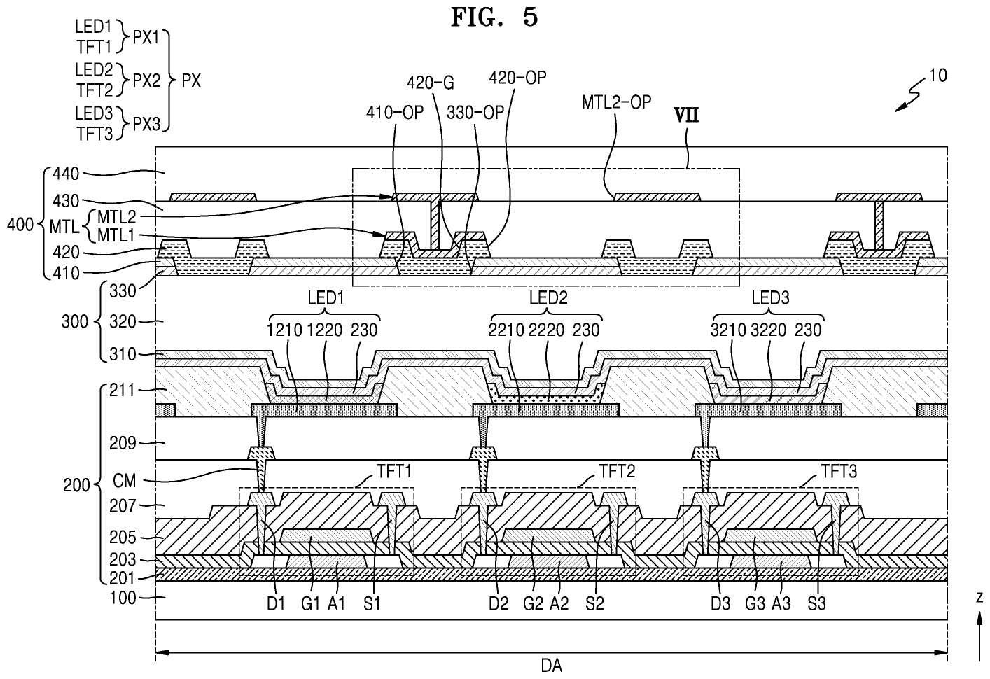

FIG. 5 is a cross-sectional view illustrating a portion of the display panel 10 according to an embodiment.

Referring to FIG. 5, the display panel 10 may include a substrate 100, a display layer 200 disposed on the substrate 100, an encapsulation layer 300 disposed on the display layer 200, and a touch layer 400 disposed on the encapsulation layer 300.

The display layer 200 including a pixel PX may be disposed on the substrate 100. The pixel PX may be arranged in the display area DA of the display panel 10. For example, the pixel PX may be arranged in the main display area (see MDA of FIG. 3), the side display area (see SDA of FIG. 3), and/or the corner display area (see CDA of FIG. 3) of the display panel 10. In other words, the pixel PX may be the main pixel (see PXm of FIG. 3), the side pixel (see PXs of FIG. 3), or the corner pixel (see PXc of FIG. 3).

The pixel PX may include a plurality of sub-pixels. For example, the pixel PX may include first to third sub-pixels PX1, PX2, and PX3. The sub-pixels may each include a light-emitting diode and a thin-film transistor. For example, the first to third sub-pixels PX1, PX2, and PX3 may respectively include first to third light-emitting diodes LED1, LED2, and LED3 each configured to emit light of a certain color, and first to third thin-film transistors TFT1, TFT2, and TFT3.

The substrate 100 may include a glass material or plastic polymer resin. The substrate 100 including the polymer resin may be flexible, rollable, or bendable. The substrate 100 may have a multilayer structure including a polymer resin-containing layer and an inorganic layer.

The first to third light-emitting diodes LED1, LED2, and LED3 corresponding to the first to third sub-pixels PX1, PX2, and PX3 may be respectively electrically connected to the first to third thin-film transistors TFT1, TFT2, and TFT3 on the substrate 100.

The first light-emitting diode LED1 corresponding to the first sub-pixel PX1 may be electrically connected to the first thin-film transistor TFT1. The first thin-film transistor TFT1 may include a first active layer A1, a first gate electrode G1 overlapping a portion of the first active layer A1, and a first source electrode S1 and a first drain electrode D1 each in direct contact with a portion of the first active layer A1.

The second light-emitting diode LED2 corresponding to the second sub-pixel PX2 may be electrically connected to the second thin-film transistor TFT2. The second thin-film transistor TFT2 may include a second active layer A2, a second gate electrode G2 overlapping a portion of the second active layer A2, and a second source electrode S2 and a second drain electrode D2 each in direct contact with a portion of the second active layer A2.

The third light-emitting diode LED3 corresponding to the third sub-pixel PX3 may be electrically connected to the third thin-film transistor TFT3. The third thin-film transistor TFT3 may include a third active layer A3, a third gate electrode G3 overlapping a portion of the third active layer A3, and a third source electrode S3 and a third drain electrode D3 each in direct contact with a portion of the third active layer A3.

The first to third gate electrodes G1, G2, and G3 may each include at least one material selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), and may have a single-layer or multilayer structure including the material described above.

A buffer layer 201 may be between the first to third active layers A1, A2, and A3 and the substrate 100 so as to prevent infiltration of impurities. A gate insulating layer 203 may be between the first to third active layers A1, A2, and A3 and the first to third gate electrodes G1, G2, and G3. An interlayer insulating layer 205 may be disposed on the first to third gate electrodes G1, G2, and G3. The buffer layer 201, the gate insulating layer 203, and the interlayer insulating layer 205 may each include an inorganic insulating material, such as silicon oxide (SiOₓ), silicon nitride (SiNₓ), silicon oxynitride (SiON), aluminum oxide (AlOₓ), aluminum nitride (AlNₓ), titanium oxide (TiOₓ), or titanium nitride (TiNₓ).

The first to third source electrodes S1, S2, and S3 may be disposed on the interlayer insulating layer 205 and may be respectively connected to the first to third active layers A1, A2, and A3 through contact holes formed in the interlayer insulating layer 205 and the gate insulating layer 203. The first to third source electrodes S1, S2, and S3 may each include at least one selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), and may include a single layer or layers including the material described above.

The first to third drain electrodes D1, D2, and D3 may be disposed on the interlayer insulating layer 205 and may be respectively connected to the first to third active layers A1, A2, and A3 through contact holes formed in the interlayer insulating layer 205 and the gate insulating layer 203. The first to third drain electrodes D1, D2, and D3 may each include at least one selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), and may include a single layer or layers including the material described above. In some embodiments, the first to third source electrodes S1, S2, and S3 and the first to third drain electrodes D1, D2, and D3 may include the same material.

A first organic insulating layer 207 may be disposed on the first to third thin-film transistors TFT1, TFT2, and TFT3. For example, the first organic insulating layer 207 may be disposed to cover the first to third source electrodes S1, S2, and S3 and the first to third drain electrodes D1, D2, and D3. The first organic insulating layer 207 may include an organic insulating material, such as acryl, benzocyclobutene, polyimide, or hexamethyldisiloxane. The first organic insulating layer 207 may have a plurality of contact holes that respectively overlap the first to third drain electrodes D1, D2, and D3.

A contact metal CM may be disposed on the first organic insulating layer 207. The contact metal CM may include aluminum (Al), copper (Cu), and/or titanium (Ti), and may include a single layer or layers including the material described above. A plurality of contact metals CM may be provided. The contact metals CM may be respectively in direct contact with the first to third drain electrodes D1, D2, and D3 through contact holes formed in the first organic insulating layer 207.

A second organic insulating layer 209 may be between the first organic insulating layer 207 and the first to third sub-pixels PX1, PX2, and PX3. The second organic insulating layer 209 may include an organic insulating material, such as acryl, benzocyclobutene, polyimide, or hexamethyldisiloxane. The second organic insulating layer 209 may include contact holes respectively overlapping the contact metals CM.

The first to third sub-pixel electrodes 1210, 2210, and 3210 may be disposed on the second organic insulating layer 209. In some embodiments, the first to third sub-pixel electrodes 1210, 2210, and 3210 may be formed as reflective electrodes. For example, the first to third sub-pixel electrodes 1210, 2210, and 3210 may be formed by forming a reflective layer of silver (Ag), magnesium (Mg), aluminum (Al), platinum (Pt), palladium (Pd), gold (Au), nickel (Ni), neodymium (Nd), iridium (Ir), chromium (Cr), or any compound thereof and disposing, on the reflective layer, a layer formed of indium tin oxide (ITO), indium zinc oxide (IZO), zinc oxide (ZnO), or indium oxide (In2O3). The disclosure is not limited thereto. The first to third sub-pixel electrodes 1210, 2210, and 3210 may be formed of various materials, and the structures of the first to third sub-pixel electrodes 1210, 2210, and 3210 may also be variously modified. For example, the first to third sub-pixel electrodes 1210, 2210, and 3210 may be formed as a single layer or layers.

The first to third sub-pixel electrodes 1210, 2210, and 3210 may be respectively electrically connected to the overlapping contact metals CM through contact holes formed in the second organic insulating layer 209.

FIG. 5 illustrates that the first to third thin-film transistors TFT1, TFT2, and TFT3 and the first to third sub-pixel electrodes 1210, 2210, and 3210 are respectively electrically connected to each other through the contact metals CM, but the disclosure is not limited thereto. In an embodiment, the contact metals CM may be omitted, and one organic insulating layer may be between the first to third thin-film transistors TFT1, TFT2, and TFT3 and the first to third sub-pixel electrodes 1210, 2210, and 3210. In an embodiment, three or more organic insulating layers may be between the first to third thin-film transistors TFT1, TFT2, and TFT3 and the first to third sub-pixel electrodes 1210, 2210, and 3210, and the first to third thin-film transistors TFT1, TFT2, and TFT3 may be respectively electrically connected to the first to third sub-pixel electrodes 1210, 2210, and 3210 through a plurality of contact metals.

A sub-pixel defining layer 211 may cover the edge areas (or edges) of the first to third sub-pixel electrodes 1210, 2210, and 3210. In other words, the sub-pixel defining layer 211 may include a plurality of openings respectively extending to and exposing central portions of the first to third sub-pixel electrodes 1210, 2210, and 3210. The openings of the sub-pixel defining layer 211 may respectively define emission areas of the first to third sub-pixels PX1, PX2, and PX3.

First to third intermediate layers 1220, 2220, and 3220 may be respectively disposed on the first to third sub-pixel electrodes 1210, 2210, and 3210. In an embodiment, the first to third intermediate layers 1220, 2220, and 3220 may be respectively disposed within the openings of the sub-pixel defining layer 211 to correspond to the first to third sub-pixel electrodes 1210, 2210, and 3210.

The first to third intermediate layers 1220, 2220, and 3220 may each include an organic emission layer including a low molecule weight material or a high molecular weight material. The first to third intermediate layers 1220, 2220, and 3220 may each have a single-layer or multilayer structure including a hole injection layer, a hole transport layer, an organic emission layer, an electron transport layer, and/or an electron injection layer.

Opposite electrodes 230 may be respectively disposed on the first to third intermediate layers 1220, 2220, and 3220. The opposite electrodes 230 may be integrally formed to cover the first to third intermediate layers 1220, 2220, and 3220. In some embodiments, the opposite electrode 230 may be formed as a (semi) transparent electrode. For example, the opposite electrode 230 may include at least one material selected from Ag, Al, Mg, Li, Ca, Cu, LiF/Ca, LiF/AI, MgAg, and CaAg, and may be formed as a thin-film having a thickness of several to tens of nanometers (nm). In some embodiments, the composition and material of the opposite electrode 230 are not limited thereto, and various modifications are possible.

The encapsulation layer 300 may be disposed on the opposite electrode 230. The encapsulation layer 300 may include at least one inorganic encapsulation layer and at least one organic encapsulation layer. For example, the encapsulation layer 300 may include a first inorganic encapsulation layer 310, an organic encapsulation layer 320, and a second inorganic encapsulation layer 330, which are sequentially stacked in this stated order.

Even when cracks occur in the encapsulation layer 300 due to the multilayer structure of the encapsulation layer 300, such cracks may not propagate between the first inorganic encapsulation layer 310 and the organic encapsulation layer 320 or between the organic encapsulation layer 320 and the second inorganic encapsulation layer 330. The encapsulation layer 300 may prevent or minimize infiltration of ambient moisture or oxygen into the display layer 200.

The first inorganic encapsulation layer 310 and the second inorganic encapsulation layer 330 may each include an inorganic insulating material, such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

The organic encapsulation layer 320 may relieve internal stress of the first inorganic encapsulation layer 310 and/or the second inorganic encapsulation layer 330. The organic encapsulation layer 320 may include a polymer-based material. For example, the organic encapsulation layer 320 may include polyethylene terephthalate, polyethylene naphthalate, polycarbonate, polyimide, polyethylene sulfonate, polyoxymethylene, polyarylate, hexamethyldisiloxane, acrylic resin (e.g., polymethylmethacrylate, polyacrylic acid, etc.), or any combination thereof.

The second inorganic encapsulation layer 330 may include a plurality of third openings 330-OP. The third openings 330-OP of the second inorganic encapsulation layer 330 may be arranged in areas between adjacent sub-pixels. For example, the third openings 330-OP may be arranged in an area between the first sub-pixel PX1 including the first light-emitting diode LED1 and the second sub-pixel PX2 including the second light-emitting diode LED2 and/or an area between the second sub-pixel PX2 including the second light-emitting diode LED2 and the third sub-pixel PX3 including the third light-emitting diode LED3. In an embodiment, the third openings 330-OP may pass through the second inorganic encapsulation layer 330.

The touch layer 400 may be disposed on the encapsulation layer 300. The touch layer 400 may include first to fourth touch insulating layers 410, 420, 430, and 440 and first and second touch electrodes MTL1 and MTL2, collectively touch electrodes MTL.

The first touch insulating layer 410 may be disposed on the second inorganic encapsulation layer 330. The first touch insulating layer 410 may include first openings 410-OP arranged in areas between adjacent sub-pixels. The first openings 410-OP of the first touch insulating layer 410 may overlap and be above the third openings 330-OP of the second inorganic encapsulation layer 330. The first openings 410-OP may pass through the first touch insulating layer 410. Accordingly, a portion of the upper surface of the organic encapsulation layer 320 may be exposed through the first openings 410-OP and the third openings 330-OP.

The second touch insulating layer 420 may be disposed on the first touch insulating layer 410. A portion of the second touch insulating layer 420 may at least partially (e.g., completely) fill the first openings 410-OP of the first touch insulating layer 410 and the third openings 330-OP of the second inorganic encapsulation layer 330. The second touch insulating layer 420 may be in direct contact with the organic encapsulation layer 320 within the first openings 410-OP and the third openings 330-OP. The second touch insulating layer 420 may include second openings 420-OP that respectively overlap and are above the sub-pixels. For example, the second touch insulating layer 420 may include the second openings 420-OP that respectively overlap the first to third light-emitting diodes LED1, LED2, and LED3. The second opening 420-OP may be spaced apart from the first opening 410-OP and the third opening 330-OP. The second openings 420-OP may pass through the second touch insulating layer 420. Accordingly, a portion of the upper surface of the first touch insulating layer 410 may be exposed through the second openings 420-OP. The second touch insulating layer 420 may include grooves 420-G that respectively overlap the first openings 410-OP and the third openings 330-OP.

The first and second touch insulating layers 410 and 420 may each include an inorganic insulating material, such as silicon oxide (SiOₓ), silicon nitride (SiNₓ), or silicon oxynitride (SiON).

The first touch electrode MTL1 may be disposed on the second touch insulating layer 420. A portion of the first touch electrode MTL1 may be arranged in the groove 420-G of the second touch insulating layer 420.

The third touch insulating layer 430 may be disposed on the first touch electrode MTL1. The third touch insulating layer 430 may cover the first touch electrode MTL1 and may planarize the surface on which the second touch electrode MTL2 is disposed. The third touch insulating layer 430 may at least partially (e.g., completely) fill the second openings 420-OP of the second touch insulating layer 420. The third touch insulating layer 430 may be in direct contact with the first touch insulating layer 410 at the second openings 420-OP. The third touch insulating layer 430 may have a plurality of contact holes that allow the first and second touch electrodes MTL1 and MTL2 to be in direct contact with each other.

The second touch electrode MTL2 may be disposed on the third touch insulating layer 430. The second touch electrode MTL2 may function as a sensor configured to sense a touch input of a user. The first touch electrode MTL1 may function as a connection portion that connects the patterned second touch electrodes MTL2 to each other in one direction. In some embodiments, both the first touch electrode MTL1 and the second touch electrode MTL2 may function as sensors. The first and second touch electrodes MTL1 and MTL2 may be electrically connected to each other through a contact hole formed in the third touch insulating layer 430.

The fourth touch insulating layer 440 may be disposed on the second touch electrode MTL2 and may cover the second touch electrode MTL2. Although not illustrated in FIG. 5, additional layers, such as an optical functional layer, may be disposed on the fourth touch insulating layer 440.

The first and second touch electrodes MTL1 and MTL2 may each include a metal layer or a transparent conductive layer. The metal layer may include molybdenum (Mo), silver (Ag), titanium (Ti), copper (Cu), aluminum (AI), and any alloy thereof. The transparent conductive layer may include a transparent conductive oxide (e.g., ITO, IZO, ZnO, indium tin zinc oxide (ITZO), etc.), conductive polymer (e.g., polyethylene dihydroxythiophene (PEDOT: poly-(3,4)-ethylene-dihydroxy thiophene)), metal nanowires, carbon nanotubes, or graphene.

The third and fourth touch insulating layers 430 and 440 may each include an inorganic material or an organic material. When the third and fourth touch insulating layers 430 and 440 each include an inorganic material, the third and fourth touch insulating layers 430 and 440 may each include at least one selected from silicon nitride (SiNₓ), aluminum nitride (AlNₓ), zirconium nitride (ZrNₓ), titanium nitride (TiNₓ), hafnium nitride (HfNₓ), tantalum nitride (TaNₓ), silicon oxide (SiOₓ), aluminum oxide (AlOₓ), titanium oxide (TiOₓ), tin oxide (SnOₓ), cerium oxide (CeOₓ), and silicon oxynitride (SiON). When the third and fourth touch insulating layers 430 and 440 each include an organic material, the third and fourth touch insulating layers 430 and 440 may each include at least one selected from acrylic resin, methacrylic resin, polyisoprene, vinyl-based resin, epoxy-based resin, urethane-based resin, cellulose-based resin, and perylene-based resin.

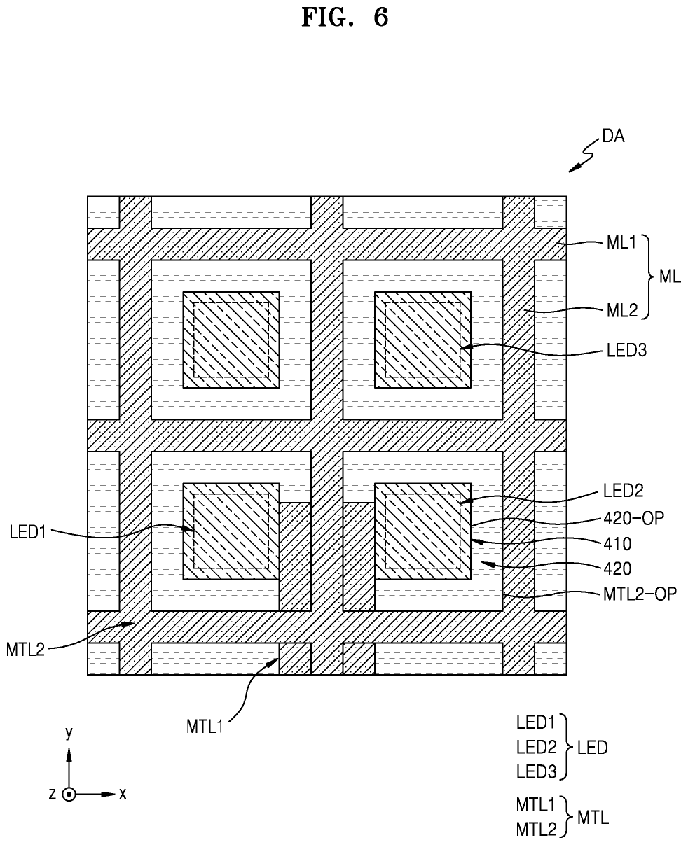

FIG. 6 is an enlarged plan view illustrating a portion of a display panel according to an embodiment.

Referring to FIG. 6, a second touch electrode MTL2 may include a conductive line ML passing between adjacent light-emitting diodes. The conductive line ML may include a first conductive line ML1 and a second conductive line ML2. The first conductive line ML1 may extend in the first direction (e.g., the ±x direction), and the second conductive line ML2 may extend in the second direction (e.g., the ty direction). The first and second conductive lines ML1 and ML2 may cross each other and form a plurality of openings MTL2-OP of the second touch electrode MTL2. In other words, the second touch electrode MTL2 may have a mesh or net shape including the openings MTL2-OP. The light-emitting diodes LED may be respectively arranged in the openings MTL2-OP of the second touch electrode MTL2. For example, first to third light-emitting diodes LED1, LED2, and LED3, collectively the light-emitting diodes LED, may be respectively arranged in the openings MTL2-OP of the second touch electrode MTL2.

A first touch electrode MTL1 may be disposed below the second touch electrode MTL2 while overlapping the second touch electrode MTL2. In an embodiment, the first touch electrode MTL1 may extend in the second direction (e.g., the ±y direction), and the length of the first touch electrode MTL1 in the first direction (e.g., the ±x direction) may be greater than the length of the second touch electrode MTL2 in the first direction (e.g., the ±x direction). In an embodiment, the first touch electrode MTL1 may extend in the first direction (e.g., the ±x direction), and the length of the first touch electrode MTL1 in the second direction (e.g., the ty direction) may be greater than the length of the second touch electrode MTL2 in the second direction (e.g., the ty direction).

The second opening 420-OP of the second touch insulating layer 420 may overlap the opening MTL2-OP of the second touch electrode MTL2. The size of the second opening 420-OP of the second touch insulating layer 420 may be less than the size of the opening MTL2-OP of the second touch electrode MTL2. Accordingly, a portion of the upper surface of the second touch insulating layer 420 may be exposed through the opening MTL2-OP of the second touch electrode MTL2. A portion of the upper surface of the first touch insulating layer 410 may be exposed through the second opening 420-OP of the second touch insulating layer 420.

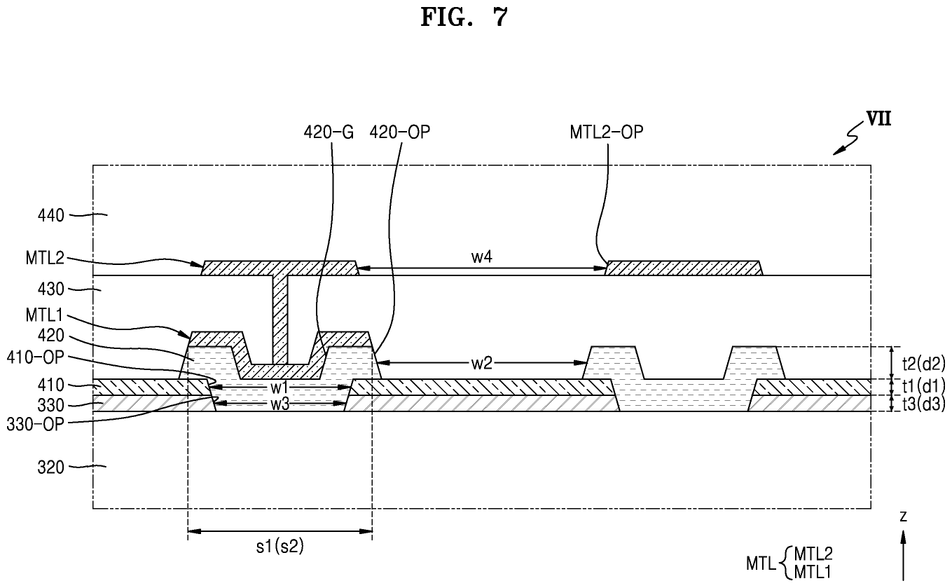

FIG. 7 is an enlarged cross-sectional view illustrating a portion of the display panel according to an embodiment. FIG. 7 is an enlarged cross-sectional view of region VII of FIG. 5.

Referring to FIG. 7, the first touch insulating layer 410, the second touch insulating layer 420, and the second inorganic encapsulation layer 330 may respectively include the first to third openings 410-OP, 420-OP, and 330-OP.

Hereinafter, the width of the opening may be understood to mean the minimum width of the opening. For example, a first width w1, i.e., a width of the first opening 410-OP of the first touch insulating layer 410, may refer to the minimum width of the first opening 410-OP. A second width w2, i.e., a width of the second opening 420-OP of the second touch insulating layer 420, may refer to the minimum width of the second opening 420-OP. A third width w3, i.e., a width of the third opening 330-OP of the second inorganic encapsulation layer 330, may refer to the minimum width of the third opening 330-OP. A fourth width w4, i.e., a width of the opening MTL2-OP of the second touch electrode MTL2, may refer to the minimum width of the opening MTL2-OP of the second touch electrode MTL2.

The first touch insulating layer 410 may include the first opening 410-OP, and the second inorganic encapsulation layer 330 may include the third opening 330-OP. The side surface of the first touch insulating layer 410 adjacent to the first opening 410-OP and the side surface of the second inorganic encapsulation layer 330 adjacent to the third opening 330-OP may be on the same plane. In an embodiment, the side surface of each of the first touch insulating layer 410 and the second inorganic encapsulation layer 330 may be tapered with respect to the upper surface of the organic encapsulation layer 320. Accordingly, the first width w1 may be greater than the third width w3. In an embodiment, when the side surface of each of the first touch insulating layer 410 and the second inorganic encapsulation layer 330 is perpendicular to the upper surface of the organic encapsulation layer 320, the first width w1 may be equal to the third width w3.

Although FIG. 7 illustrates that the first width w1 and the third width w3 are less than the second width w2, the disclosure is not limited thereto. In an embodiment, the first width w1 and/or the third width w3 may be equal to or greater than the second width w2.

The second touch insulating layer 420 may include the second opening 420-OP and the groove 420-G. The second opening 420-OP may be arranged in an area between the first and third openings 410-OP and 330-OP adjacent to each other. The second opening 420-OP may pass through the second touch insulating layer 420. The groove 420-G may overlap the first and third openings 410-OP and 330-OP. The groove 420-G may not pass through the second touch insulating layer 420. The width of the groove 420-G may be less than the first width w1 and/or the third width w3.

Although FIG. 7 illustrates that the second width w2 is less than the fourth width w4, the disclosure is not limited thereto. In an embodiment, the second width w2 may be equal to the fourth width w4.

When the width of the upper surface of the first touch insulating layer 410 is defined as a first length s1 and the width of the lower surface of the first touch electrode MTL1 is defined as a second length s2, the first length s1 may be equal to the second length s2. For example, the side surface of the first touch insulating layer 410 and the side surface of the first touch electrode MTL1 may be on the same plane.

The thickness of the first touch insulating layer 410 may be defined as a first thickness t1, and the depth of the first opening 410-OP may be defined as a first depth d1. The thickness of the second touch insulating layer 420 may be defined as a second thickness t2, and the depth of the second opening 420-OP may be defined as a second depth d2. The thickness of the second inorganic encapsulation layer 330 may be defined as a third thickness t3, and the depth of the third opening 330-OP may be defined as a third depth d3.

The first to third openings 410-OP, 420-OP, and 330-OP may respectively pass through the first touch insulating layer 410, the second touch insulating layer 420, and the second inorganic encapsulation layer 330. In other words, the first depth d1 may be equal to the first thickness t1, the second depth d2 may be equal to the second thickness t2, and the third depth d3 may be equal to the third thickness t3.

In some embodiments, the sum of the first to third thicknesses t1, t2, and t3 may be about 7,000 Å or more. In some embodiments, the sum of the first to third thicknesses t1, t2, and t3 may be about 10,000 Å. In some embodiments, the sum of the first and third thicknesses t1 and t3 may be equal to the second thickness t2. For example, the sum of the first and third thicknesses t1 and t3 may be about 5,000 Å and the second thickness t2 may be about 5,000 Å. In some embodiments, the first thickness t1 may be equal to the third thickness t3. For example, the first thickness t1 may be about 2,500 Å and the third thickness t3 may be about 2,500 Å. According to an embodiment, the reliability of the display panel may be improved by securing sufficient thicknesses of the first touch insulating layer 410, the second touch insulating layer 420, and the second inorganic encapsulation layer 330. In addition, because the first to third openings 410-OP, 420-OP, and 330-OP are disposed, the occurrence of cracks due to stress during bending may be prevented. Of course, the scope of the disclosure is not limited to these values.

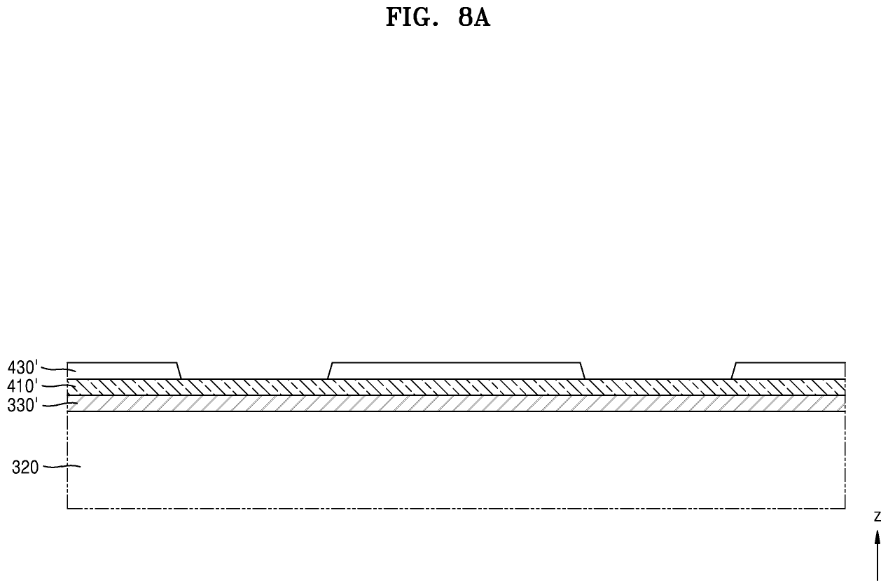

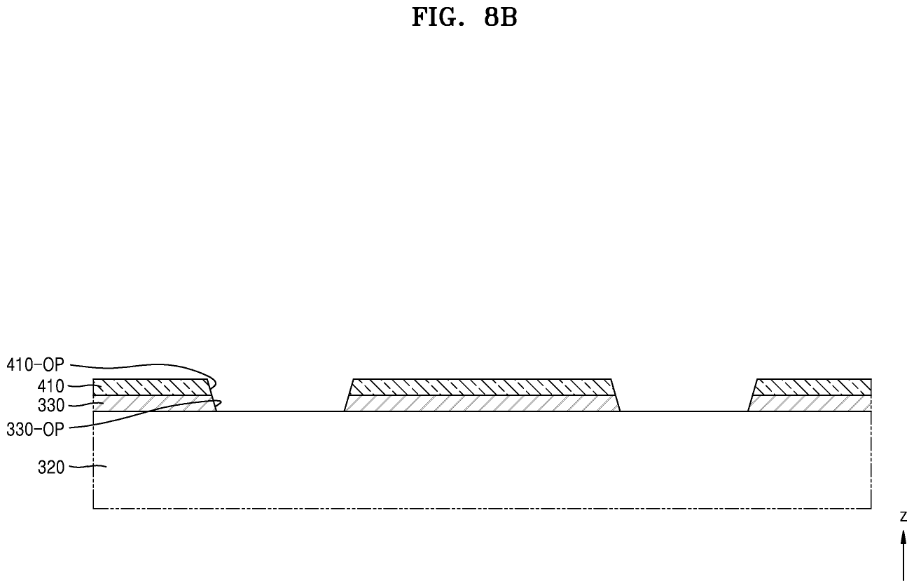

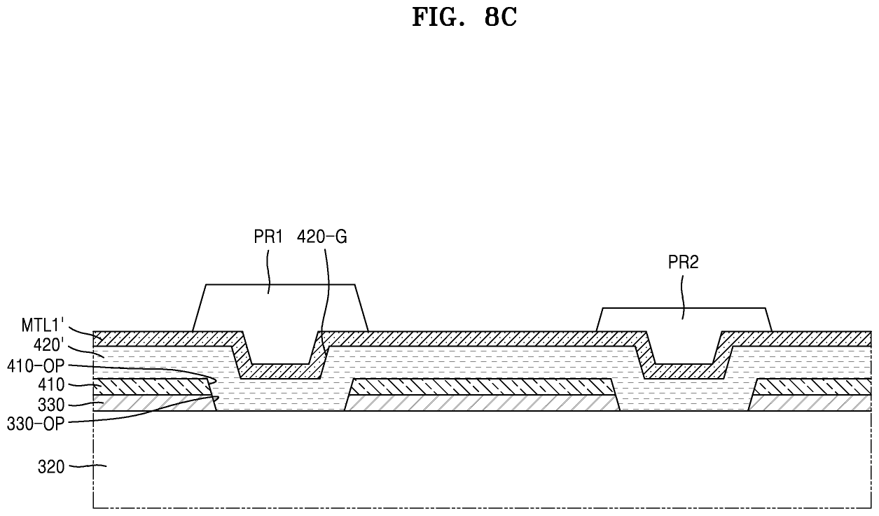

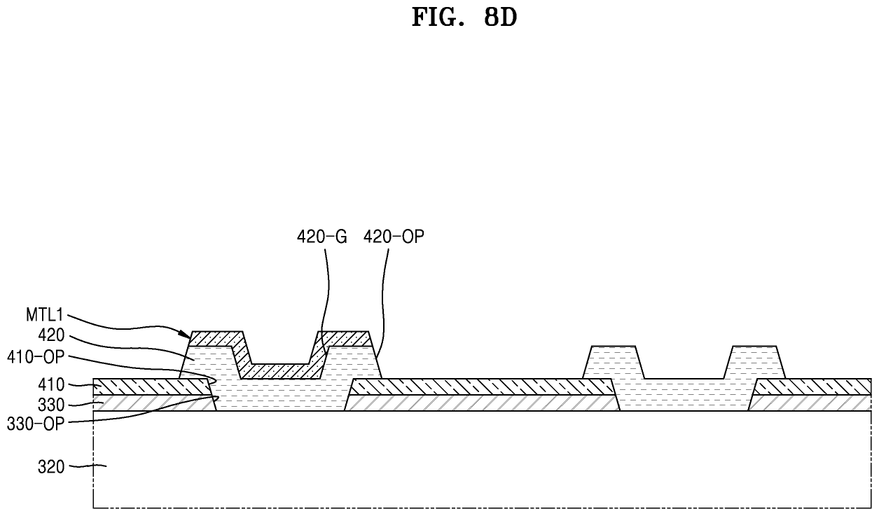

FIGS. 8A to 8D are cross-sectional views schematically illustrating a process of manufacturing a display panel, according to an embodiment. For example, FIGS. 8A to 8D may be cross-sectional views illustrating the process of manufacturing the display panel illustrated in FIG. 7, according to an embodiment.

Referring to FIG. 8A, in a state in which the organic encapsulation layer 320 is formed, a second encapsulation material layer 330′ and a first insulating material layer 410′ may be disposed on the organic encapsulation layer 320. The second encapsulation material layer 330′ may include the same material as that of the second inorganic encapsulation layer (see 330 of FIG. 5). The first insulating material layer 410′ may include the same material as that of the first touch insulating layer (see 410 of FIG. 5). A third insulating material layer 430′ may be disposed on the first insulating material layer 410′. The third insulating material layer 430′ may include an opening that extends to and exposes a portion of the first insulating material layer 410′. The third insulating material layer 430′ may include the same material as that of the third touch insulating layer (see 430 of FIG. 5).

Referring to FIGS. 8A and 8B together, a portion of the first insulating material layer 410′ and the second encapsulation material layer 330′ may be removed by using the third insulating material layer 430′ as a mask. In an embodiment, the first touch insulating layer 410 and the second inorganic encapsulation layer 330 may be patterned. The process of removing a portion of the first insulating material layer 410′ and the second encapsulating material layer 330′ may include dry etching and dry ashing.

The first touch insulating layer 410 may be a portion remaining after removing a portion of the first insulating material layer 410′, and the first opening 410-OP may be a space where a portion of the first insulating material layer 410′ is removed. The second inorganic encapsulation layer 330 may be a portion remaining after removing a portion of the second encapsulation material layer 330′, and the third opening 330-OP may be a space where a portion of the second encapsulation material layer 330′ is removed.

Because the first touch insulating layer 410 and the second inorganic encapsulation layer 330 may be patterned at the same time, the side surfaces of the first touch insulating layer 410 and the second inorganic encapsulation layer 330 where the first and third openings 410-OP and 330-OP are formed may be on the same plane.

Referring to FIG. 8C, a second insulating material layer 420′, a first electrode material layer MTL1′, a first photoresist PR1, and a second photoresist PR2 may be disposed on the embodiment illustrated in FIG. 8B.

The second insulating material layer 420′ may cover the first touch insulating layer 410 and the second inorganic encapsulation layer 330. The second insulating material layer 420′ may at least partially (e.g., completely) fill the first and third openings 410-OP and 330-OP, and may include a groove 420-G that overlaps the first and third openings 410-OP and 330-OP. The second insulating material layer 420′ may be in direct contact with the organic encapsulation layer 320 at the first and third openings 410-OP and 330-OP. The first electrode material layer MTL1′ may cover the second insulating material layer 420′.

The first photoresist PR1 may be disposed on the first electrode material layer MTL1′ while overlapping one of the first openings 410-OP. The second photoresist PR2 may be spaced apart from the first photoresist PR1 and may be disposed on the first electrode material layer MTL1′ while overlapping another one of the first openings 410-OP. The thicknesses of the first photoresist PR1 may be different from the thickness of the second photoresist PR2. For example, the first photoresist PR1 may be a full-tone mask and the second photoresist PR2 may be a half-tone mask.

Referring to FIGS. 8C and 8D together, a portion of each of the first electrode material layer MTL1′ and the second insulating material layer 420′ may be removed by using the first and second photoresists PR1 and PR2 as a mask. In an embodiment, the first touch electrode MTL1 and the second touch insulating layer 420 may be patterned. The process of removing a portion of each of the first electrode material layer MTL1′ and the second insulating material layer 420′ may include dry etching and wet etching.

Because the first photoresist PR1 is a full-tone mask, a portion of the first electrode material layer MTL1′ and a portion of the second insulating material layer 420′ may remain in an area overlapping the first photoresist PR1. The remaining portion of the first electrode material layer MTL1′ may be the first touch electrode MTL1. The remaining portion of the second insulating material layer 420′ may be a portion of the second touch insulating layer 420.

Because the second photoresist PR2 is a halftone mask, the first electrode material layer MTL1′ may be removed from an area overlapping the second photoresist PR2, and a portion of the second insulating material layer 420′ may remain therein. The remaining portion of the second insulating material layer 420′ may be a portion of the second touch insulating layer 420.

Both the first electrode material layer MTL1′ and the second insulating material layer 420′ may be removed from areas that do not overlap the first and second photoresists PR1 and PR2, and a portion of the upper surface of the first touch insulating layer 410 may be exposed. The second opening 420-OP of the second touch insulating layer 420 may be a space where a portion of the second insulating material layer 420′ is removed.

Because the first touch electrode MTL1 and the second touch insulating layer 420 may be patterned at the same time, the side surface of the first touch electrode MTL1 and the side surface of the second touch insulating layer 420 may be on the same plane. Thereafter, the embodiment illustrated in FIG. 7 may be implemented by disposing the third and fourth touch insulating layers (see 430 and 440 of FIG. 7) and the second touch electrode (see MTL2 of FIG. 7).

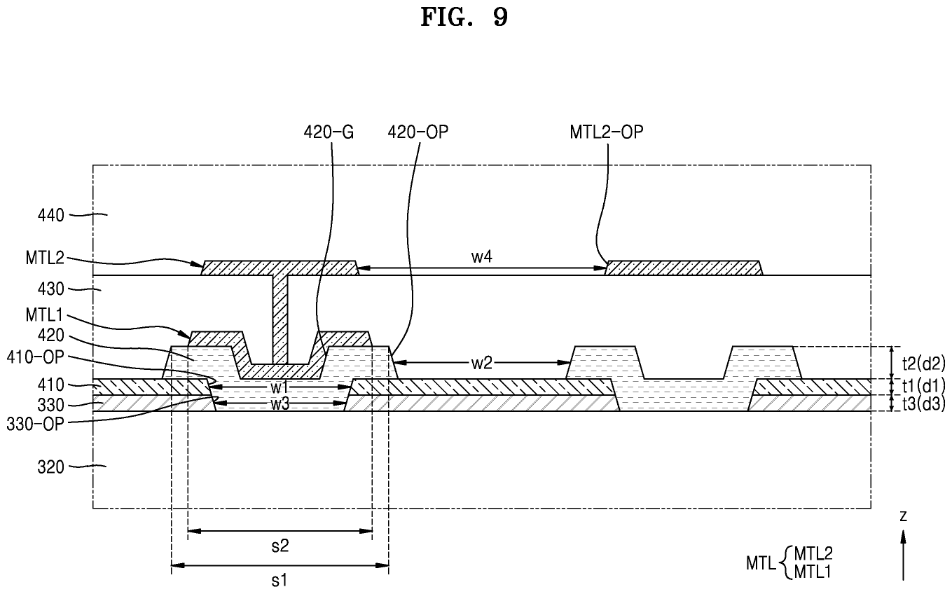

FIG. 9 is an enlarged cross-sectional view illustrating a portion of a display panel according to an embodiment.

Referring to FIG. 9, the width of the upper surface of the second touch insulating layer 420 may be defined as a first length s1, and the width of the lower surface of the first touch electrode MTL1 may be defined as a second length s2.

In an embodiment, the first length s1 may be greater than the second length s2. Accordingly, the side surface of the first touch electrode MTL1 may be spaced apart from the side surface of the second touch insulating layer 420. The second touch insulating layer 420 may be in direct contact with the third touch insulating layer 430 in an area adjacent to the area overlapping the first touch electrode MTL1.

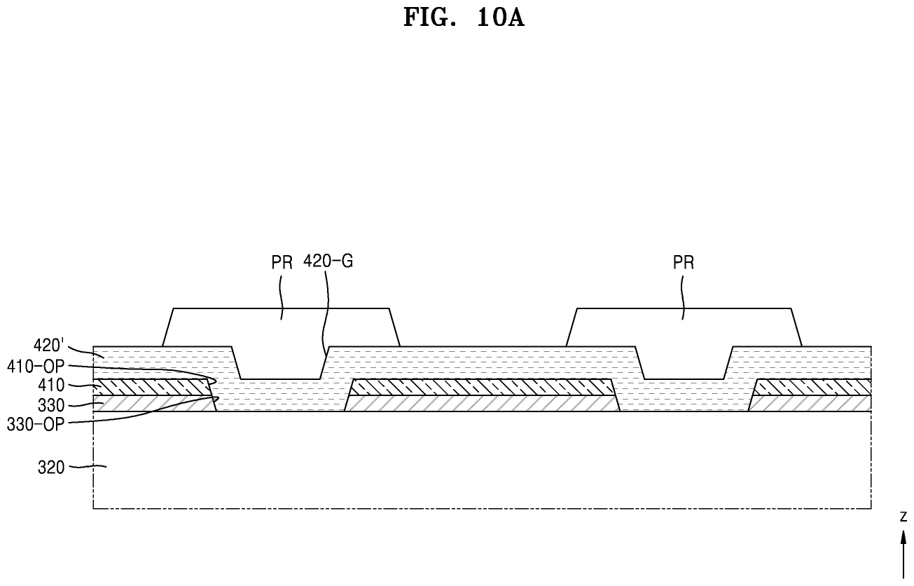

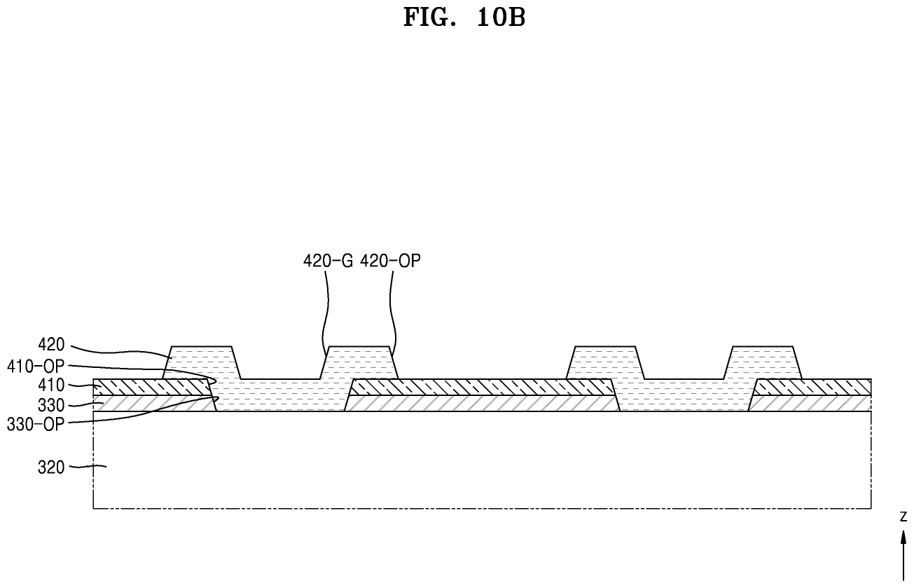

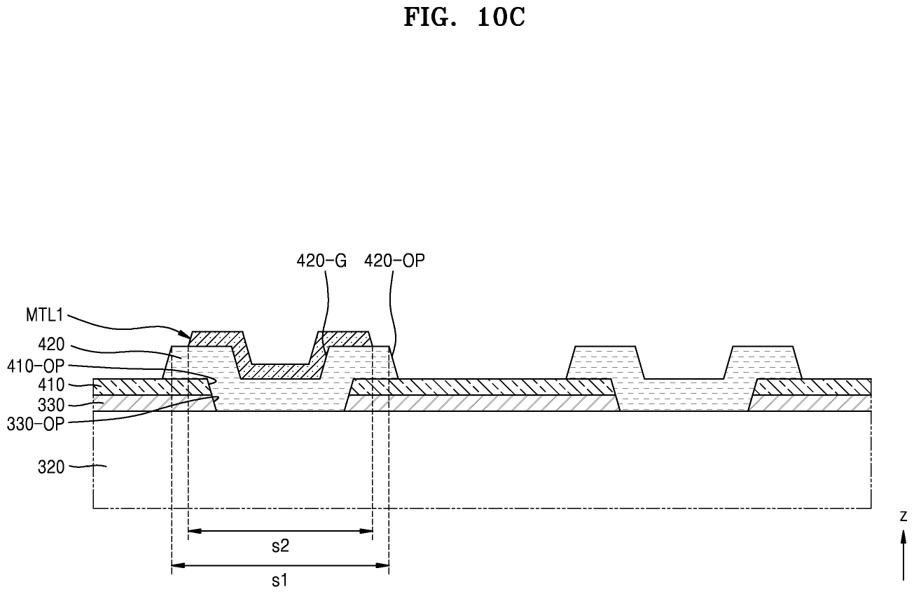

FIGS. 10A to 10C are cross-sectional views schematically illustrating a process of manufacturing a display panel, according to an embodiment. For example, FIGS. 10A to 10C may be cross-sectional views illustrating the process of manufacturing the display panel illustrated in FIG. 9, according to an embodiment.

Referring to FIG. 10A, a second insulating material layer 420′ and a photoresist PR may be disposed on the embodiment illustrated in FIG. 8B. A portion of the second insulating material layer 420′ may at least partially (e.g., completely) fill the first and third openings 410-OP and 330-OP. The photoresist PR may include an opening overlapping an area between the first openings 410-OP. The respective portions of the photoresist PR may have the same thickness.

Referring to FIGS. 10A and 10B together, the second touch insulating layer 420 may be formed by removing a portion of the second insulating material layer 420′. In an embodiment, the second touch insulating layer 420 may be patterned.

The second touch insulating layer 420 may be a portion remaining after removing a portion of the second insulating material layer 420′, and the second opening 420-OP may be a space where a portion of the second insulating material layer 420′ is removed. The second opening 420-OP may be arranged in an area between the first openings 410-OP adjacent to each other.

Referring to FIG. 10C, a first touch electrode MTL1 may be formed on the embodiment illustrated in FIG. 10B. The first touch electrode MTL1 may be patterned by using a mask separate from the second touch insulating layer 420. Accordingly, the side surface of the first touch electrode MTL1 and the side surface of the second touch insulating layer 420 may not be on the same plane. In an embodiment, the first length s1 may be different from the second length s2. Thereafter, the embodiment illustrated in FIG. 9 may be implemented by disposing the third and fourth touch insulating layers (see 430 and 440 of FIG. 9) and the second touch electrode (see MTL2 of FIG. 9).

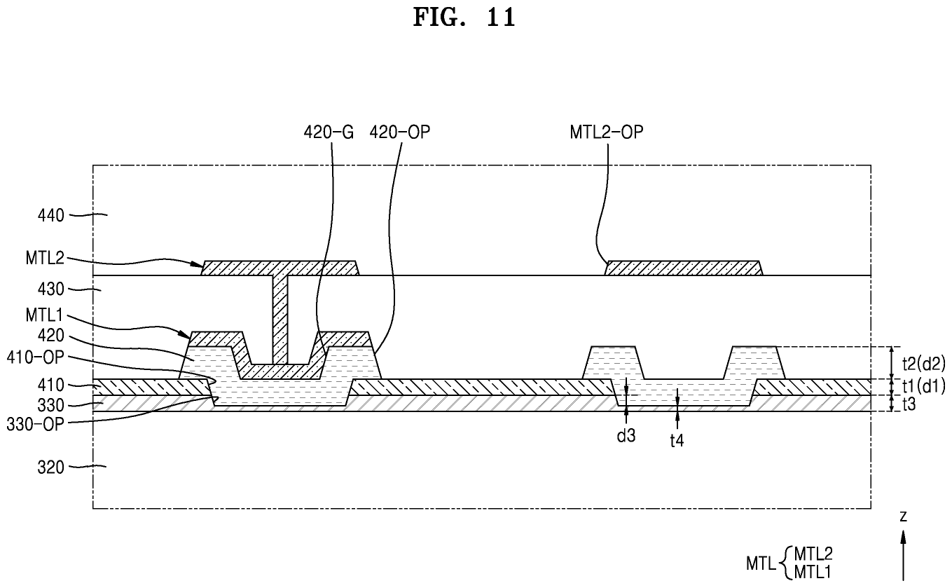

FIG. 11 is an enlarged cross-sectional view illustrating a portion of a display panel according to an embodiment.

Referring to FIG. 11, the third opening 330-OP of the second inorganic encapsulation layer 330 may not pass through the second inorganic encapsulation layer 330.

In some embodiments, the third opening 330-OP may be a blind hole that does not pass through the second inorganic encapsulation layer 330. For example, when the thickness of the second inorganic encapsulation layer 330 is defined as a third thickness t3 and the depth of the third opening 330-OP is defined as a third depth d3, the third depth d3 may be less than the third thickness t3. In an area overlapping the third opening 330-OP, the second inorganic encapsulation layer 330 may have a fourth thickness t4 that is less than the third thickness t3. In an embodiment, the sum of the third depth d3 and the fourth thickness t4 may be equal to the third thickness t3.

In some embodiments, the fourth thickness t4 may be less than the third depth d3. For example, the third thickness t3 may be about 2,500 Å, the third depth d3 may be about 2,000 Å, and the fourth thickness t4 may be about 500 Å. In some embodiments, the fourth thickness t4 may be about 500 Å or less.

In some embodiments, because the third opening 330-OP does not pass through the second inorganic encapsulation layer 330, the second touch insulating layer 420 may be spaced apart from the organic encapsulation layer 320 without being in direct contact with the organic encapsulation layer 320. In an area overlapping the first and third openings 410-OP and 330-OP, the second touch insulating layer 420 may be in direct contact with a portion of the upper surface of the second inorganic encapsulation layer 330.

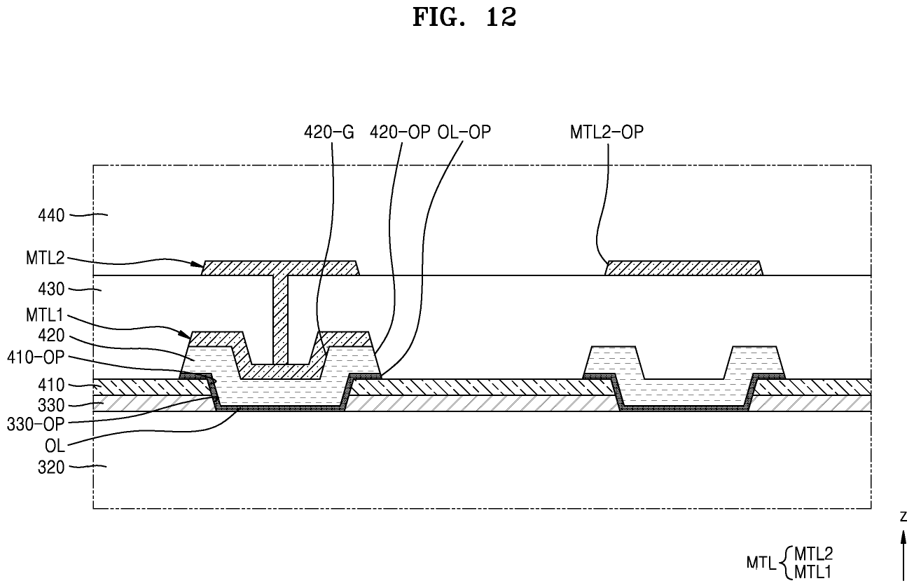

FIG. 12 is an enlarged cross-sectional view illustrating a portion of a display panel according to an embodiment.

Referring to FIG. 12, an organic layer OL may be disposed below a second touch insulating layer 420.

The organic layer OL may be between a first touch insulating layer 410 and the second touch insulating layer 420. A portion of the organic layer OL may be arranged in the first and third openings 410-OP and 330-OP. The organic layer OL may cover a portion of the upper surface of the first touch insulating layer 410, and a portion of the organic layer OL may be arranged in the first opening 410-OP and may cover the side surface of the first touch insulating layer 410. In addition, a portion of the organic layer OL may be arranged in the third opening 330-OP and may cover a side surface of a second inorganic encapsulation layer 330. The organic layer OL may be in direct contact with the organic encapsulation layer 320 within the third opening 330-OP and may cover a portion of an upper surface of an organic encapsulation layer 320 exposed through the third opening 330-OP.

The organic layer OL may include an opening OL-OP overlapping a second opening 420-OP. A portion of the upper surface of the first touch insulating layer 410 may be exposed through the opening OL-OP of the organic layer OL. At this time, the first and third touch insulating layers 410 and 430 may be in direct contact with each other through the opening OL-OP of the organic layer OL. Because the organic layer OL includes the opening OL-OP disposed below the second touch insulating layer 420 and overlapping the second opening 420-OP, it may be stated that the upper surface of the organic layer OL is covered by the second touch insulating layer 420. A portion of the third touch insulating layer 430 may be arranged in the opening OL-OP of the organic layer OL and may cover the side surface of the organic layer OL. The organic layer OL may additionally relieve stress that may occur within the display panel and may also prevent the propagation of cracks occurring in some layers.

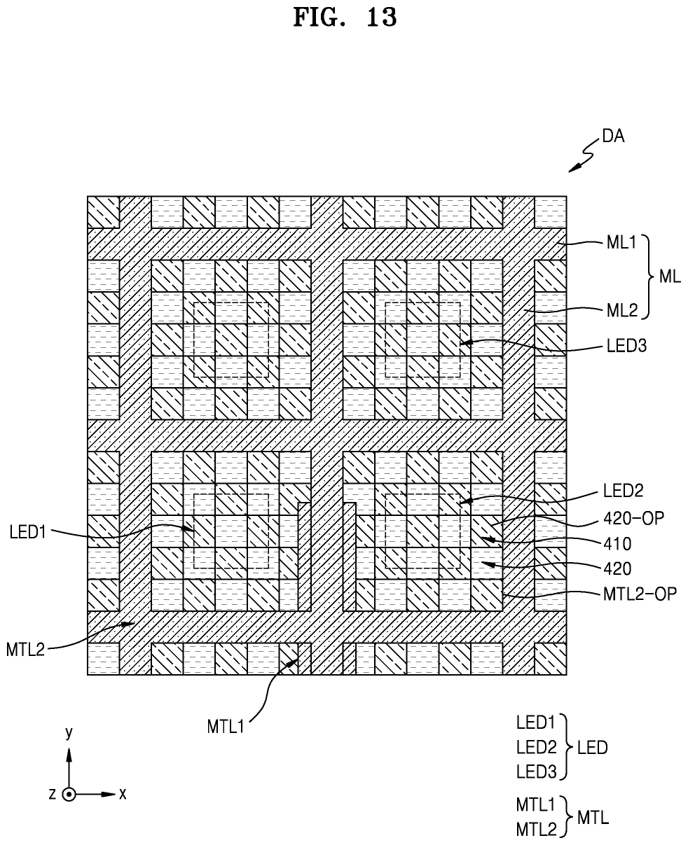

FIG. 13 is an enlarged plan view illustrating a portion of a display panel according to an embodiment.

Referring to FIG. 13, unlike in FIG. 6, one of openings MTL2-OP of a second touch electrode MTL2 may overlap a plurality of second openings 420-OP.

In an embodiment, second openings 420-OP of a second touch insulating layer 420 may be arranged in a check pattern or a checkerboard shape. Accordingly, the second touch insulating layer 420 and an upper surface of a first touch insulating layer 410 exposed by the second openings 420-OP may also be arranged in a check pattern or a checkerboard shape.

Light-emitting diodes LED may respectively overlap the second openings 420-OP. For example, a first light-emitting diode LED1 may partially overlap four second openings 420-OP. A second light-emitting diode LED2 may completely overlap one second opening 420-OP and partially overlap four second openings 420-OP. A third light-emitting diode LED3 may partially overlap four second openings 420-OP.

Although FIG. 13 illustrates that the second opening 420-OP has a substantially square shape in which each side of the second opening 420-OP is parallel to each side of the opening MTL2-OP of the second touch electrode MTL2, the disclosure is not limited thereto. In an embodiment, the shape of the second opening 420-OP may be variously modified. For example, the second opening 420-OP may have a trapezoidal shape, a diamond shape, a circular shape, or an elliptical shape. The number of second openings 420-OP overlapping the openings MTL2-OP of the second touch electrode MTL2 may also variously change.

According to an embodiment, the display apparatus including the structure capable of reducing stress or strain without reducing the thickness of the inorganic insulating layer of the touch layer may be implemented. Accordingly, the reliability of the display apparatus may be secured and the occurrence of cracks may be prevented during the bending process. The scope of the disclosure is not limited by such an effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a display layer comprising a plurality of light-emitting diodes;
a first insulating layer disposed on the display layer and comprising a first opening disposed in a gap between two light-emitting diodes adjacent to each other among the plurality of light-emitting diodes; and
a second insulating layer disposed on the first insulating layer and comprising a second opening spaced apart from the first opening.

2. The display apparatus of claim 1, wherein a portion of the second insulating layer at least partially fills the first opening of the first insulating layer.

3. The display apparatus of claim 1, wherein the second opening is disposed above one of the two light-emitting diodes adjacent to each other.

4. The display apparatus of claim 1, wherein, in a plan view, the first opening has a shape surrounding the second opening.

5. The display apparatus of claim 4, further comprising a touch electrode disposed on the second insulating layer and comprising a conductive line passing between the two light-emitting diodes adjacent to each other in a plan view,
wherein the conductive line is disposed above the first opening.

6. The display apparatus of claim 1, further comprising an encapsulation layer between the display layer and the first insulating layer,
wherein the encapsulation layer comprises:
a first inorganic encapsulation layer;
an organic encapsulation layer disposed on the first inorganic encapsulation layer; and
a second inorganic encapsulation layer disposed on the organic encapsulation layer and comprising a third opening disposed below the first opening.

7. The display apparatus of claim 6, wherein a depth of the first opening is equal to a thickness of the first insulating layer, and
a depth of the third opening is less than or equal to a thickness of the second inorganic encapsulation layer.

8. The display apparatus of claim 1, further comprising an organic layer between the first insulating layer and the second insulating layer.

9. The display apparatus of claim 8, wherein the organic layer comprises an opening disposed below the second opening.

10. The display apparatus of claim 1, wherein the second insulating layer comprises a plurality of second openings, and
one of the plurality of light-emitting diodes overlaps two or more of the plurality of second openings.

11. The display apparatus of claim 1, further comprising a display area in which the plurality of light-emitting diodes are arranged and a peripheral area arranged outside the display area,
wherein the first opening and the second opening are arranged in the display area.

12. A display apparatus comprising:
a display layer comprising a plurality of light-emitting diodes;
an encapsulation layer disposed on the display layer; and
a touch layer disposed on the encapsulation layer,
wherein the touch layer comprises:
a touch electrode; and
a first insulating layer and a second insulating layer between the touch electrode and the encapsulation layer,
the first insulating layer comprises a first opening,
the second insulating layer comprises a second opening, and
a center of the first opening and a center of the second opening are spaced apart from each other.

13. The display apparatus of claim 12, wherein a portion of the second insulating layer at least partially fills the first opening.

14. The display apparatus of claim 12, wherein the second opening is disposed above one of the plurality of light-emitting diodes.

15. The display apparatus of claim 12, wherein the touch electrode comprises a conductive line and an opening defined by the conductive line,
the conductive line of the touch electrode is disposed above the first opening of the first insulating layer, and
the opening of the touch electrode is disposed above the second opening of the second insulating layer.

16. The display apparatus of claim 12, wherein the touch layer further comprises a third insulating layer disposed on the second insulating layer, and
the third insulating layer is in direct contact with the first insulating layer at the second opening.

17. The display apparatus of claim 12, wherein the encapsulation layer comprises:
a first inorganic encapsulation layer;
an organic encapsulation layer on the first inorganic encapsulation layer; and
a second inorganic encapsulation layer on the organic encapsulation layer, and
the second inorganic encapsulation layer comprises a third opening disposed below the first opening of the first insulating layer.

18. The display apparatus of claim 17, wherein the first opening passes through the first insulating layer, and
the third opening is located over at least a portion of the second inorganic encapsulation layer in a depth direction.

19. The display apparatus of claim 12, further comprising an organic layer between the first insulating layer and the second insulating layer.

20. The display apparatus of claim 12, further comprising a display area in which the plurality of light-emitting diodes are arranged and a peripheral area surrounding the display area,
wherein the first opening and the second opening are arranged in the display area.
